(19) United States
(12) Patent Application Publication
(10) Pub. No.: US 2007/0247931 A1
(43) Pub. Date: Oct. 25, 2007

(54) Internal voltage generator for a semiconductor memory apparatus

(75) Inventor: Kyung Whan Kim, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 11/647,484

(22) Filed: Dec. 29, 2006

(30) Foreign Application Priority Data
Apr. 6, 2006 (KR) 10-2006-0031277

(51) Int. Cl. G11C 5/14

(52) U.S. Cl. 365/189.09

(57) ABSTRACT

An internal voltage generator for a semiconductor memory apparatus, including: a reference voltage generator that outputs a reference voltage. A driver controller receives the reference voltage and generating a driver control signal using the reference voltage. An amplifier circuit amplifies the driver control signal. And, a driver outputs an internal voltage in response to an output signal of the amplifier.

### CROSS-REFERENCE TO RELATED PATENT APPLICATION

This application claims the benefit of Korean Patent Application No. 10-2006-0031277, filed on Apr. 6, 2006, in the Korean Intellectual Property Office, the disclosure of which is incorporated herein in its entirety by reference.

### BACKGROUND OF THE INVENTION

1. Technical Field

The present invention disclosed herein relates to semiconductor memory apparatuses, and more particularly, to an internal voltage generator for a semiconductor memory apparatus that is configured to reinforce current drivability, even with low power.

2. Related Art

With the development of semiconductor technology, the number of memory cells for storing data in a semiconductor memory apparatus is gradually increasing. Therefore, a unit cell that stores data is designed and manufactured to be as small as possible, enabling a semiconductor memory apparatus to have the largest number of unit cells possible. As is well known in this field, recent design criteria for memory cells is in the sub-micron range. Further, the rate of power consumption in a semiconductor memory apparatus must be reduced while the operation frequency gets higher and higher. To meet these requirements, power source voltages in a semiconductor memory apparatus are continuously decreased. Recently, most semiconductor memory apparatuses have a power source voltage of 1.5V.

The power source voltage for a semiconductor memory apparatus is supplied to the memory apparatus externally, the external power source voltage is usually converted to an internal voltage in consideration of the internal circuits of the memory apparatus.

A semiconductor memory apparatus may include core and peripheral regions. The core region may include a memory cell array in which memory cells are integrated, and a sense amplifier for sensing and amplifying cell data. The peripheral region may include an input/output buffer, decoders, and other control circuits, for conducting input/output operations with data and addresses. The core region uses its own power source voltage with a core-specific internal voltage (VCORE) that is lower than an external power source voltage. The peripheral region uses its own power source voltage with a peripheral-specific internal voltage (VPERI) that is lower than an external power source voltage. The core-specific internal voltage is normally lower than the peripheral-specific internal voltage, because memory cells in the core region are arranged in a more highly microscopic pattern than the circuit pattern of the peripheral region.

A semiconductor memory apparatus also needs to have an internal voltage generator for generating voltages such as a cell plate voltage, bit-line precharge voltage, etc. As these internal voltages operate in the core region, they are usually generated from the core-specific internal voltage (VCORE). Such cell plate and bit-line precharge voltages are normally half (½) the level of the core-specific internal voltage (VCORE), i.e., a half core level (Half-VCORE).

FIG. 1 is a graph of power models with the aforementioned internal voltages compared to an external voltage level, assuming that the external power source voltage VDD is 1.8V and the core-specific internal voltage VCORE is 1.5V. As can be seen in the graph of FIG. 1, after the external power source voltage VDD reaches a target level, the core-specific internal voltage VCORE maintains a constant level of 1.5V and the half core internal voltage Half-VCORE maintains ½ the level of VCORE.

With the trend of lower power source voltages in memory apparatuses, there is a need for an internal voltage generator to provide such a half core internal voltage Half-VCORE more effectively. FIG. 2 is a circuit diagram of an internal voltage generator capable of supplying the half core internal voltage Half-VCORE in a semiconductor memory apparatus according to the conventional art, exemplarily showing a circuit for generating a bit-line precharge voltage VBLP. Also, a circuit for supplying a cell plate voltage to memory cells may have the same structure as shown in FIG. 2.

The internal voltage generator shown in FIG. 2 is composed of a reference voltage generator 100 that outputs a reference voltage REF, a driver controller 200 that generates pull-up and pull-down control signals PU0 and PD0 from the reference voltage REF and the bit-line precharge voltage VBLP, and a driver 300 that outputs the bit-line precharge voltage VBLP in response to the pull-up and pull-down control signals PU0 and PD0.

The reference voltage generator 100, as shown in FIG. 2, may be a voltage divider including two resistors R1 and R2 which are serially coupled between the core-specific internal voltage VCORE terminal and a ground voltage VSS terminal. Here, the resistors R1 and R2 have equal resistance, constituting a voltage division loop for a generating the reference voltage REF that is half (½) the level of the core-specific internal voltage VCORE.

The driver controller 200 is composed of a bias signal generator 200A that receives the reference voltage REF and outputs pull-up and pull-down bias voltages PBIAS and NBIAS, and an output controller 200B that receives the reference voltage REF and the bit-line precharge voltage VBLP and that generates pull-up and pull-down control signals PU0 and PD0 in response to the pull-up and pull-down bias voltages PBIAS and NBIAS.

The bias signal generator 200A includes PMOS transistors P1, P2, and P3, and NMOS transistors N1, N2, N3, and N4. The PMOS transistor P1 is switched by the reference voltage REF. The PMOS transistor is driven by the core-specific internal voltage VCORE. The PMOS transistor P2 is serially coupled with the PMOS transistor P1 and is also switched by the reference voltage REF. The NMOS transistor N1 is coupled with the PMOS transistor P2. The NMOS transistor N2 is coupled between the NMOS transistor N1 and the ground voltage VSS terminal. The PMOS transistor P3 is driven by the core-specific internal voltage VCORE. The NMOS transistor N3 is coupled to the PMOS transistor P3. The NMOS transistor N4 is coupled between the NMOS transistor N3 and the ground voltage VSS terminal.

In the bias signal generator 200A, the pull-up bias voltage PBIAS is output from a common node between the PMOS and NMOS transistors P3 and N3, while the pull-down bias voltage NBIAS is output from a common node B between the NMOS transistors N1 and N2. The NMOS transistors N1 and N3 form a current mirror, and the NMOS transistors N2 and N4 also operate as a current mirror. If a voltage difference between the reference voltage REF and the core-specific internal voltage VCORE becomes larger than the threshold voltages of the PMOS transistors P1 and P2, a current flows through the PMOS transistors P1 and P2. This current raises the voltage of a node A and turns the NMOS transistor N1 on to make a current flow through it. Thereby, the voltage of the node B rises to turn the NMOS transistor N2 on. Meanwhile, the NMOS transistor N3 and the NMOS transistor N1 form a current mirror, while the NMOS transistor N4 and the NMOS transistor N2 form a current mirror. According to the operation of the current mirror by the NMOS transistors N3 and N4, the PMOS transistor P3 drives a constant current from the core-specific internal voltage VCORE, resulting in the generation of the pull-up bias voltage PBIAS with a constant voltage. Further, the pull-down bias voltage NBIAS is generated at a constant voltage.

The output controller 200B is formed of PMOS transistors P4, P5, P6, and P7, and NMOS transistors N5, N6, N7, and N8. The PMOS transistor P4 is applied with the core-specific internal voltage VCORE, and is driven by the pull-up bias voltage PBIAS. The NMOS transistor N5 is coupled between the PMOS transistor P4 and an input node of the reference voltage REF, and generates a voltage NG which is higher than the reference voltage REF by the threshold voltage of an NMOS transistor. The PMOS transistor P6 is coupled between the NMOS transistor N5 and the input node of the reference voltage REF, and generates a voltage PG which is lower than the reference voltage REF by the threshold voltage of a PMOS transistor. The NMOS transistor N6 is coupled with the PMOS transistor P6 and the ground voltage VSS terminal, and is driven by the pull-down bias voltage NBIAS. The PMOS transistor P5 is applied with the core-specific internal voltage VCORE, and is driven by the pull-up bias voltage PBIAS. The NMOS transistor N7 is coupled between the PMOS transistor P5 and an output node of the bit-line precharge voltage VBLP, and is driven by the voltage NG. The PMOS transistor P7 is coupled with the output node of the bit-line precharge voltage VBLP, and is driven by the voltage PG. The NMOS transistor N8 is coupled between the PMOS transistor P7 and the ground voltage VSS terminal, and is driven by the pull-down bias voltage NBIAS.

The output controller 200B is configured to generate the voltage NG which is higher than the reference voltage REF by the threshold voltage of an NMOS transistor and the voltage PG which is lower than the reference voltage REF by the threshold voltage of a PMOS transistor, and to generate the pull-up and pull-down control signals PU0 and PD0 in response to the pull-up and pull-down bias voltages PBIAS and NBIAS.

The driver 300 is composed of a pull-up driver PU that pulls the bit-line precharge voltage VBLP up in response to the pull-up control signal PU0, and a pull-down driver PD that pulls the bit-line precharge voltage VBLP down in response to the pull-down control signal PD0.

An operation for driving the bit-line precharge voltage VBLP as an internal voltage by means of the circuit configuration shown in FIG. 2 is as follows.

If the bit-line precharge voltage VBLP decreases, a voltage gap between the voltage NG and the bit-line precharge voltage VBLP is enlarged so more current flows through the NMOS transistor N7. Thereby, the voltage level of the pull-up control signal PU0 falls, which increases the level of the bit-line precharge voltage VBLP through the pull-up driver PU. As a result, the bit-line precharge voltage VBLP recovers to its target level.

If the bit-line precharge voltage VBLP increases, a voltage gap between the voltage PG and the bit-line precharge voltage VBLP is enlarged so more current flows through the PMOS transistor P7. Thereby, the voltage level of the pull-down control signal PD0 rises, which decreases the level of the bit-line precharge voltage VBLP through the pull-down driver PD. As a result, the bit-line precharge voltage VBLP recovers to its target level.

In the internal voltage generator constructed as shown in FIG. 2, the pull-up driver PU is turned on when a voltage gap between the pull-up control signal PU0 and the core-specific internal voltage VCORE is higher than the threshold voltage of a PMOS transistor (i.e., the pull-up driver PU), and the pull-down driver PD is turned on when a voltage gap between the pull-down control signal PD0 and the ground voltage VSS is higher than the threshold voltage of an NMOS transistor (i.e., the pull-down driver PD).

With the present trend of lower external power source voltages in semiconductor memory apparatuses, the core-specific internal voltage VCORE is also continuously becoming lower. Thus, it is difficult to assure sufficient voltage gaps between the pull-up control signal PU0 and the core-specific internal voltage VCORE and between the pull-down control signal PD0 and the ground voltage VSS. In this case, it is inevitable that current drivability is degraded.

In order to overcome the aforementioned problems, it may be possible to provide pull-up and pull-down drivers with PMOS and NMOS transistors having lower threshold voltages. However, this method causes an increase in the leakage current in the drivers, which prevents fast recovery of the bit-line precharge voltage VBLP and causes too much current dissipation in a stand-by mode. Therefore, this method is unsuitable for a memory apparatus in a mobile system that must operate with minimum power consumption. Further, since the size of the driver needs to be large so as to enhance the current drivability, it occupies too much of the internal voltage generator.

### SUMMARY

Embodiments of the present invention provide an internal voltage generator for a semiconductor memory apparatus that improves current drivability in a driver even with a lower power source voltage.

An embodiment of the present invention provides an internal voltage generator for a semiconductor memory apparatus comprising: a reference voltage generator configured to output a reference voltage; a driver controller configured to receive the reference voltage and generate a driver control signal using the reference voltage; an amplifier circuit configured to amplify and output the driver control signal; and a driver configured to output an internal voltage in response to an output signal of the amplifier.

Another embodiment of the present invention provides an internal voltage generator for a semiconductor memory apparatus comprising: a reference voltage generator configured to output a reference voltage; a driver controller configured to generate first pull-up and pull-down control signals using the reference voltage; a pull-up amplifier configured to receive the reference voltage and generate a second pull-up control signal from the first pull-up control signal; a pull-down amplifier configured to receive the reference voltage and generate a second pull-down control signal from the first pull-down control signal; and a driver configured to output an internal voltage in response to the second pull-up and pull-down control signals.

Still another embodiment of the present invention provides an internal voltage generator for a semiconductor memory apparatus comprising: a reference voltage generator configured to output a reference voltage; a driver controller configured to generate first pull-up and pull-down control signals in response to a variation of an internal voltage corresponding to the reference voltage; a pull-up amplifier configured to generate a second pull-up control signal by differentially amplifying the first pull-up control signal and the reference voltage; a pull-down amplifier configured to generate a second pull-down control signal by differentially amplifying the first pull-down control signal and the reference voltage; a pull-up driver configured to pull up the internal voltage or be turned off in response to the second pull-up control signal; and a pull-down driver configured to pull down the internal voltage or be turned off in response to the second pull-down control signal.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified. In the figures:

FIG. 1 is a graph of power models with internal voltages compared to an external voltage level;

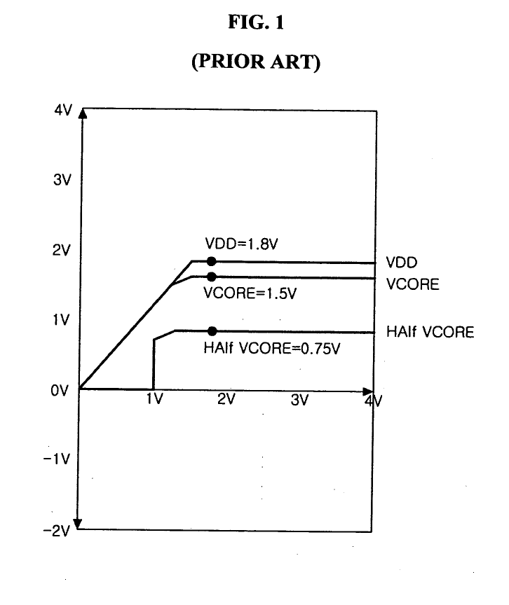

FIG. 2 is a circuit diagram of an internal voltage generator for a semiconductor memory apparatus according to the conventional art;

FIG. 3 is a circuit diagram of an exemplary internal voltage generator for a semiconductor memory apparatus in accordance with an embodiment of the present invention;

FIG. 4 is a circuit diagram of an exemplary internal voltage generator for a semiconductor memory apparatus in accordance with another embodiment of the present invention; and

FIG. 5 is a graph comparing simulation results for the current drivability of the internal voltage generators shown in FIGS. 2 and 3.

### DETAILED DESCRIPTION OF EXEMPLARY EMBODIMENT

Preferred embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Like reference numerals refer to like elements throughout the accompanying figures.

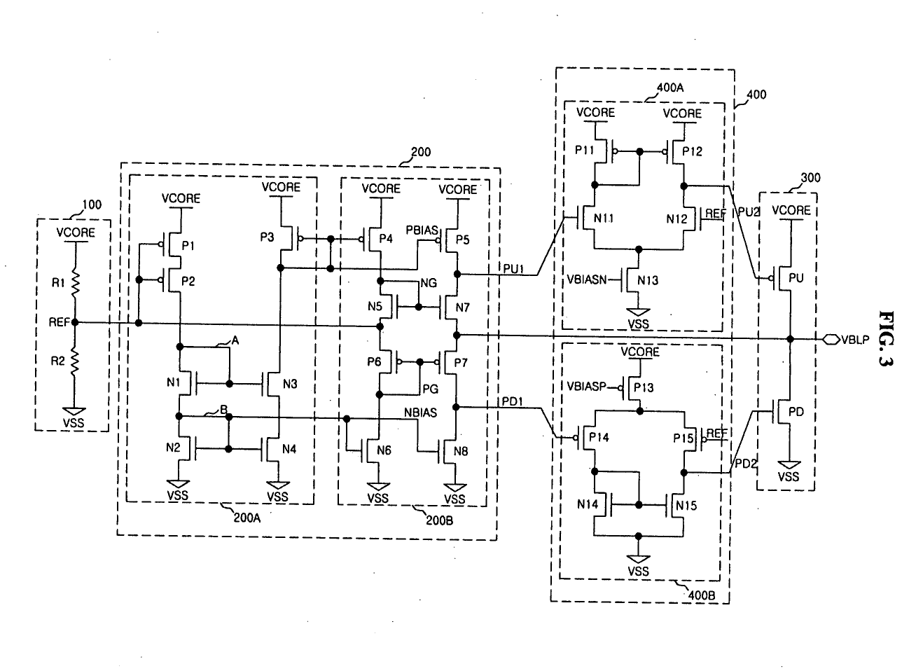

FIG. 3 is a circuit diagram of an internal voltage generator for a semiconductor memory apparatus in accordance with an embodiment of the present invention, which generates a bit-line precharge voltage VBLP with a half core internal voltage Half-VCORE.

Referring to FIG. 3, the internal voltage generator according to the present invention may include a reference voltage generator 100 that provides a reference voltage REF, a driver controller 200 that generates a driver control signal in response to the reference voltage REF, an amplifier circuit 400 that operates to amplify and output the driver control signal, and a driver 300 that provides an bit-line precharge voltage VBLP in response to an output signal of the amplifier circuit 400.

The reference voltage generator 100, as shown in FIG. 3, forms a voltage divider including two resistors R1 and R2 which may be serially coupled between the core-specific internal voltage VCORE terminal and a ground voltage VSS terminal. From a node between the resistors R1 and R2, forming a voltage division loop, the reference voltage REF is generated with half (½) the level of the core-specific internal voltage VCORE.

The driver controller 200 may include a bias signal generator 200A that receives the reference voltage REF and outputs pull-up and pull-down bias voltages PBIAS and NBIAS, and an output controller 200B that receives the reference voltage REF and the bit-line precharge voltage VBLP and that generates first pull-up and pull-down control signals PU1 and PD1 in response to the pull-up and pull-down bias voltages PBIAS and NBIAS.

The amplifier circuit 400 may include a pull-up amplifier 400A that generates a second pull-up control signal PU2 by amplifying the first pull-up control signal PU1 in response to the reference voltage REF, and a pull-down amplifier 400B that generates a second pull-down control signal PD2 by amplifying the first pull-down control signal PD1 in response to the reference voltage REF.

The pull-up amplifier 400A may include a differential amplifier that receives the first pull-up control signal PU1 and the reference voltage REF. In one embodiment, the pull-up amplifier 400A forms a differential amplifier that receives the first pull-up control signal PU1 and the reference voltage REF, and is activated by a drive signal VBIASN. The pull-up amplifier 400A may comprise an input transistor N11 (e.g., NMOS transistor) that may be switched by the first pull-up control signal PU1, an input transistor N12 (e.g., NMOS transistor) that may be switched by the reference voltage REF, a drive transistor N13 (e.g., NMOS transistor) coupled with the input transistors N11 and N12 in common and is driven by the drive signal VBIASN, a PMOS transistor P11 that allows a current to flow through the input transistor N11, and a PMOS transistor P12 that allows a current to flow through the input transistor N12. The second pull-up control signal PU2 is output from a node between the PMOS transistor P12 and the input transistor N12.

The pull-down amplifier 400B may include a differential amplifier that receives the first pull-down control signal PD1 and the reference voltage REF. In one embodiment, the pull-down amplifier 400B forms a differential amplifier that receives the first pull-down control signal PD1 and the reference voltage REF, and is activated by a drive signal VBIASP. The pull-down amplifier 400B may comprise an input transistor P14 (e.g., PMOS transistor) that switches by the first pull-down control signal PD1, an input transistor P15 (e.g., PMOS transistor) that switches by the reference voltage REF, a drive transistor P13 (e.g., PMOS transistor) that is coupled with the input transistors P14 and P15 in common and supplies the internal voltage VCORE in response to the drive signal VBIASP, an NMOS transistor N14 operated by a current flowing through the input transistor P14, and an NMOS transistor N15 operated by a current flowing through the input transistor P14 and coupled with the input transistor P15. The second pull-down control signal PD2 is generated from a node between the NMOS transistor N15 and the input transistor P15.

While this embodiment is shown with an amplifier circuit 400 that is formed by the pull-up and pull-down amplifiers 400A and 400B, the amplifier circuit 400 may be implemented as another kind of circuit, e.g., a level shifter, capable of amplifying a signal to be supplied to the driver 300.

The structure of the amplifier circuit 400 including the pull-up and pull-down amplifiers 400A and 400B is provided for in one embodiment by the present invention, but it is permissible to use an alternative pull-up or pull-down amplifier 400A or 400B if other operational characteristics are required by either the pull-up driver or the pull-down driver. In the case of using an alternative, the driver controller 200 may be modified in structure.

The driver 300 may include a pull-up driver. PU that pulls the bit-line precharge voltage VBLP up in response to the second pull-up control signal PU2, and a pull-down driver PD that pulls the bit-line precharge voltage VBLP down in response to the second pull-down control signal PD2.

Hereinafter the operation of the internal voltage generator shown in FIG. 3 will be described. While the internal voltage generator according to the present invention outputs the bit-line precharge voltage VBLP, it is also used to generate a cell plate voltage VCP or another internal voltage, which has half (½) the voltage level of VCORE, as shown in FIG. 3.

For example, when the level of the bit-line precharge voltage VBLP is set at half (½) of the core-specific internal voltage VCORE, the first pull-up control signal PU1, regarding the threshold voltage of the NMOS transistor N7, is higher than half (½) the level of the core-specific internal voltage VCORE. As the reference voltage REF becomes ½ of the core-specific internal voltage VCORE, the second pull-up control signal PU2 output from the pull-up amplifier 400A increases to almost the core-specific internal voltage VCORE level in accordance with the operational characteristics of the differential amplifier. During this step, the pull-up driver PU remains turned-off. The first pull-down control signal PD1, regarding the threshold voltage of the PMOS transistor P7, is lower than half the level of the core-specific internal voltage VCORE. As the reference voltage REF becomes ½ of the core-specific internal voltage VCORE, the second pull-down control signal PD2 output from the pull-down amplifier 400B decreases to almost the ground voltage VSS level in accordance with the operational characteristics of the differential amplifier. During this step, the pull-down driver PD remains turned-off.

If the bit-line precharge voltage VBLP decreases, a voltage difference between the voltage NG and the bit-line precharge voltage VBLP in the output controller 200B increases. Accordingly, the current that flows through the NMOS transistor N7 is increased, dropping the voltage level of the first pull-up control signal PU1. Thus, when the first pull-up control signal PU1 is lower than the reference voltage REF, the second pull-up control signal PU2 decreases to almost the ground voltage VSS due to the pull-up amplifier 400A. As the pull-up driver PU is turned on and a current is supplied to the output node of the bit-line precharge voltage VBLP from the supply node of the core-specific internal voltage VCORE, the level of the bit-line precharge voltage VBLP returns to the target level, i.e., the ½ VCORE level.

If the bit-line precharge voltage VBLP increases, a voltage difference between the voltage PG and the bit-line precharge voltage VBLP in the output controller 200B increases. Accordingly, the current that flows through the PMOS transistor P7 is increased, elevating the voltage level of the first pull-down control signal PD1. Thus, when the first pull-down control signal PD1 is higher than the reference voltage REF, the second pull-down control signal PD2 increases to the core-specific internal voltage VCORE due to the pull-down amplifier 400B. The pull-down driver PD is turned on and the voltage level of the bit-line precharge voltage VBLP falls down to almost the ground voltage VSS and returns to the target level, i.e., the ½ VCORE level.

As such, the internal voltage generator of the present invention has the feature that a voltage gap between the first pull-up control signal PU1 and the reference voltage REF is amplified by the pull-up amplifier 400A, which may be a differential amplifier. This means that the current drivability of the pull-up driver PU is maximized because a voltage level of a gate terminal of the pull-up driver PU falls down to almost the ground voltage VSS due to the pull-up amplifier 400A when the pull-up driver PU of the driver 300 is turned on. Also, the internal voltage generator of the present invention has the feature that a voltage gap between the first pull-down control signal PD1 and the reference voltage REF may be amplified by the pull-down amplifier 400B, which is in the form of a differential amplifier. This means that the current drivability of the pull-down driver PD is maximized because a voltage level of a gate terminal of the pull-down driver PD rises up to almost the core-specific internal voltage VCORE due to the pull-down amplifier 400B when the pull-down driver PD of the driver 300 is turned on.

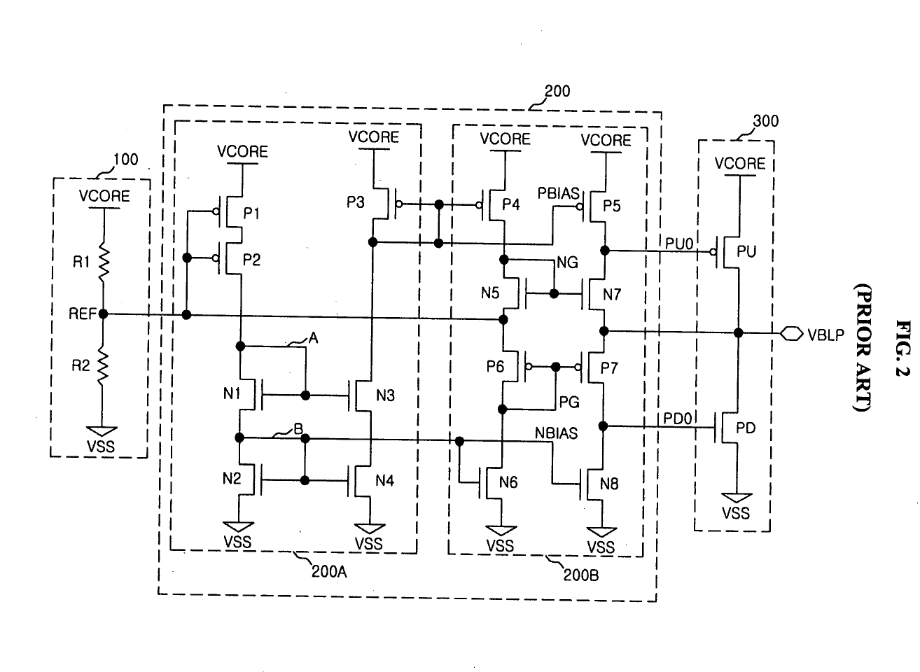

In the internal voltage generator shown in FIG. 2, the pull-up driver PU of the driver 300 is turned on when a voltage gap between the pull-up control signal PU0 and the core-specific internal voltage VCORE is over the threshold voltage of a PMOS transistor, while the pull-down driver PD of the driver 300 is turned on when a voltage gap between the pull-down control signal PD0 and the ground voltage VSS is over the threshold voltage of an NMOS transistor. However, it is difficult in practice to assure these turn-on conditions for the pull-up and pull-down drivers PU and PD, since an external power source voltage is continuously being decreased and the core-specific internal voltage VCORE is relative to the lower external power source voltage. This is because although the power source voltages continuously decrease, the threshold voltages of the pull-up and pull-down drivers for generating the bit-line precharge voltage VBLP cannot be decreased in proportion to the decreasing power source voltages. Nevertheless, the internal voltage generator according to the present invention, as shown in FIG. 3, may maximize the current drivability of the driver 300 by comparing a voltage level of the pull-up or down control signal, PU1 or PD1, which varies along the bit-line precharge voltage VBLP, with the reference voltage REF normally set at ½ the level of the core-specific internal voltage VCORE, using the differential amplifier, and supplying the second pull-up and pull-down control signals PU2 and PD2, which are obtained by amplifying the voltage gap between the pull-up or down control signal and the reference voltage, to each gate terminals of the pull-up and pull-down drivers PU and PD. In addition, the internal voltage generator shown in FIG. 3 may minimize the leakage current by reliably controlling the gate voltage of the pull-up driver PU or the pull-down driver PD to almost the core-specific internal voltage VCORE or the ground voltage VSS with the differential amplifier when variation of the bit-line precharge voltage VBLP is insufficient to inverse an output of the differential amplifier.

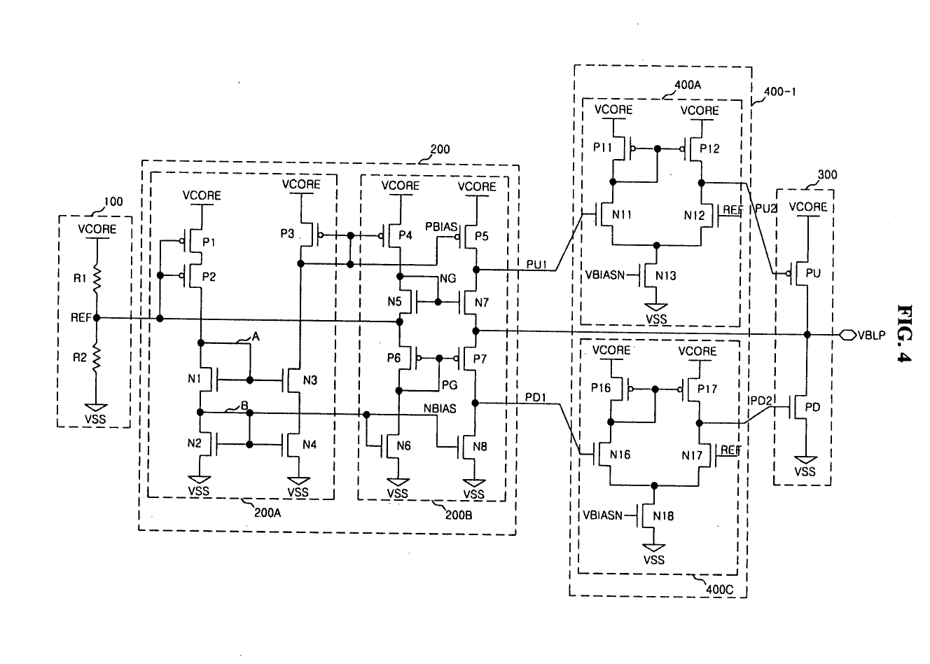

FIG. 4 is a circuit diagram of an internal voltage generator for a semiconductor memory apparatus in accordance with another embodiment of the present invention. Referring to FIG. 4, a pull-down amplifier 400C comprises input transistors N16 and N17, which are NMOS transistors, and not PMOS transistors like the input transistors P14 and P15 of the pull-down amplifier 400B shown in FIG. 3. The pull-down amplifier 400C is configured in the same way as the pull-up amplifier 400A. Even with the same circuit structure in the pull-up and pull-down amplifiers 400A and 400C, the same operational characteristics and effects can be obtained as in the former embodiment of the present invention.

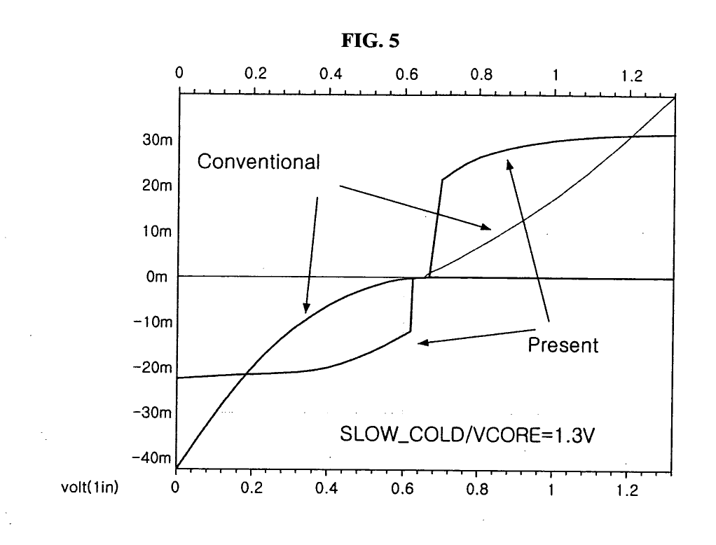

FIG. 5 is a graph comparing simulation results for the current drivability of the internal voltage generators shown in FIGS. 2 and 3. In FIG. 5, the X-axis represents the bit-line precharge voltage VBLP and the Y-axis represents the current flowing through the pull-up and pull-down drivers of the driver 300 with variation of the bit-line precharge voltage VBLP. From the graph of FIG. 5, it can be seen there is no current when the bit-line precharge voltage VBLP is ½ the level of the core-specific internal voltage VCORE. When the bit-line precharge voltage VBLP decreases, a current is generated that flows through the pull-up driver formed by the PMOS transistor. When the bit-line precharge voltage VBLP increases, a current is generated that flows through the pull-down driver formed by the NMOS transistor. As can be seen from the graph of FIG. 5, when the bit-line precharge voltage VBLP is at ½ the level of the core-specific internal voltage VCORE, the current drivability is enhanced much more than the conventional case shown in FIG. 2.

As described above, embodiments of the present invention may offer the following advantages.

It may improve current drivability of a driver by amplifying even a small variation of an internal voltage in a semiconductor memory apparatus operating with a low power source voltage.

It may maximize current drivability of a driver without enlarging the size of the driver or decreasing the threshold voltage of a transistor.

It is possible to minimize a leakage current by reliably controlling a gate voltage of the driver so it is almost the internal voltage or the ground voltage when a variation rate of the internal voltage is insufficient to inverse an output of the differential amplifier.

The above-disclosed subject-matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An internal voltage generator for a semiconductor memory apparatus, comprising:
a reference voltage generator configured to output a reference voltage;
a driver controller configured to receive the reference voltage and generate a driver control signal using the reference voltage;
an amplifier circuit configured to amplify the driver control signal and produce an output signal; and
a driver configured to receive the output signal of the amplifier and output an internal voltage in response to the output signal of the amplifier.

2. The internal voltage generator for a semiconductor memory apparatus of claim 1, wherein the reference voltage generator comprises a voltage divider.

3. The internal voltage generator for a semiconductor memory apparatus of claim 2, wherein the voltage divider comprises: two resistors serially coupled between an internal power source voltage terminal and a ground voltage terminal; and a reference voltage output node disposed between the two resistors.

4. The internal voltage generator for a semiconductor memory apparatus of claim 1, wherein the driver controller comprises:
a bias signal generator configured to receive the reference voltage and output pull-up and pull-down bias voltages; and
an output controller configured to receive the pull-up and pull-down bias voltages and generate first pull-up and pull-down control signals in response to the pull-up and pull-down bias voltages.

5. The internal voltage generator for a semiconductor memory apparatus of claim 4, wherein the bias signal generator comprises:
a first PMOS transistor configured to switch an internal power source voltage based on the reference voltage;
a second PMOS transistor serially coupled with the first PMOS transistors configured to receive the reference voltage;
a first NMOS transistor coupled with the second PMOS transistor;
a second NMOS transistor coupled between the first NMOS transistor and a ground voltage terminal;
a third PMOS transistor configured to switch the internal power source voltage;
a third NMOS transistor coupled with the third PMOS transistor; and
a fourth NMOS transistor coupled between the third NMOS transistor and the ground voltage terminal.

6. The internal voltage generator for a semiconductor memory apparatus of claim 4, wherein the output controller comprises: a fourth PMOS transistor configured to switch the internal power source voltage by the pull-up bias voltage;
a fifth NMOS transistor coupled between the fourth PMOS transistor and an input node of the reference voltage, configured to generate a first voltage higher than the reference voltage by the threshold voltage of an NMOS transistor;
a sixth PMOS transistor coupled between the fifth NMOS transistor and the input node of the reference voltage, configured to generate a second voltage lower than the reference voltage by the threshold voltage of a PMOS transistor;
a sixth NMOS transistor coupled with the sixth PMOS transistor and a ground voltage terminal, configured to be driven by the pull-down bias voltage;
a fifth PMOS transistor configured to be driven by the pull-up bias voltage and to switch the internal power source voltage;
a seventh NMOS transistor coupled between the fifth PMOS transistor and an output node of a bit-line precharge voltage, configured to be driven by the first voltage;
a seventh PMOS transistor coupled with the output node of the bit-line precharge voltage, configured to be driven by the second voltage; and
an eighth NMOS transistor coupled between the seventh PMOS transistor and the ground voltage terminal, configured to be driven by the pull-down bias voltage.

7. The internal voltage generator for a semiconductor memory apparatus of claim 4, wherein the amplifier circuit comprises:
a pull-up amplifier configured to receive the reference voltage and generate a second pull-up control signal by amplifying the first pull-up control signal in response to the reference voltage; and
a pull-down amplifier configured to receive the reference voltage and generate a second pull-down control signal by amplifying the first pull-down control signal in response to the reference voltage.

8. The internal voltage generator for a semiconductor memory apparatus of claim 7, wherein the pull-up amplifier comprises a differential amplifier configured to receive the first pull-up control signal and the reference voltage.

9. The internal voltage generator for a semiconductor memory apparatus of claim 7, wherein the pull-up amplifier comprises a level shifter configured to receive the first pull-up control signal.

10. The internal voltage generator for a semiconductor memory apparatus of claim 7, wherein the pull-down amplifier comprises a differential amplifier configured to receive the first pull-down control signal and the reference voltage.

11. The internal voltage generator for a semiconductor memory apparatus of claim 7, wherein the pull-down amplifier comprises a level shifter configured to receive the first pull-down control signal.

12. The internal voltage generator for a semiconductor memory apparatus of claim 1, wherein the driver comprises:
a pull-up driver configured to receive the output signal of the amplifier circuit and pull a bit-line precharge voltage up in response to the output signal of the amplifier circuit; and
a pull-down driver configured to receive the output signal of the amplifier circuit and pull the bit-line precharge voltage down in response to the output signal of the amplifier circuit.

13. The internal voltage generator for a semiconductor memory apparatus of claim 7, wherein the driver comprises:
a pull-up driver configured to receive the second pull-up control signal and pull a bit-line precharge voltage up in response to the second pull-up control signal; and
a pull-down driver configured to receive the second pull-down control signal and pull the bit-line precharge voltage down in response to the second pull-down control signal.

14. An internal voltage generator for a semiconductor memory apparatus, comprising:
a reference voltage generator configured to output a reference voltage;
a driver controller configured receive the reference voltage and generate first pull-up and pull-down control signals using the reference voltage;
a pull-up amplifier configured to receive the reference voltage and the first pull-up control signal and generate a second pull-up control signal from the first pull-up control signal;
a pull-down amplifier configured to receive the reference voltage and the first pull-down control signal and generate a second pull-down control signal from the first pull-down control signal; and
a driver configured receive the second pull-up and pull-down control signals and output an internal voltage in response to the second pull-up and pull-down control signals.

15. The internal voltage generator for a semiconductor memory apparatus of claim 14, wherein the reference voltage generator comprises a voltage divider.

16. The internal voltage generator for a semiconductor memory apparatus of claim 15, wherein the voltage divider comprises: two resistors serially coupled between an internal power source voltage terminal and a ground voltage terminal; and a reference voltage output node disposed between the two resistors.

17. The internal voltage generator for a semiconductor memory apparatus of claim 14, wherein the driver controller comprises:
a bias signal generator configured to receive the reference voltage and output pull-up and pull-down bias voltages; and
an output controller configured receive the pull-up and pull-down bias voltages and generate the first pull-up and pull-down control signals in response to the pull-up and pull-down bias voltages.

18. The internal voltage generator for a semiconductor memory apparatus of claim 14, wherein the pull-up amplifier comprises a differential amplifier configured to receive the first pull-up control signal and the reference voltage.

19. The internal voltage generator for a semiconductor memory apparatus of claim 18, wherein the pull-down amplifier comprises a differential amplifier configured to receive the first pull-down control signal and the reference voltage.

20. The internal voltage generator for a semiconductor memory apparatus of claim 14, wherein the driver comprises:
a pull-up driver configured to receive the second pull-up control signal and pull a bit-line precharge voltage up in response to the second pull-up control signal; and
a pull-down driver configured to receive the second pull-down control signal and pull the bit-line precharge voltage down in response to the second pull-down control signal.

21. An internal voltage generator for a semiconductor memory apparatus, comprising:
a reference voltage generator configured to output a reference voltage;
a driver controller configured to detect a variation of an internal voltage corresponding to the reference voltage and generate first pull-up and pull-down control signals in response to a variation of an internal voltage corresponding to the reference voltage;
a pull-up amplifier configured receive the first pull-up control signal and the reference voltage and generate a second pull-up control signal by differentially amplifying the first pull-up control signal and the reference voltage;
a pull-down amplifier configured to receive the first pull-down control signal and the reference voltage and generate a second pull-down control signal by differentially amplifying the first pull-down control signal and the reference voltage;
a pull-up driver configured receive the second pull-up control signal and pull up the internal voltage or be turned off in response to the second pull-up control signal; and
a pull-down driver configured to receive the second pull-down control signal and pull down the internal voltage or be turned off in response to the second pull-down control signal.

22. The internal voltage generator for a semiconductor memory apparatus of claim 21, wherein the reference voltage generator comprises a voltage divider.

23. The internal voltage generator for a semiconductor memory apparatus of claim 22, wherein the voltage divider comprises:
two resistors serially coupled between an internal power source voltage terminal and a ground voltage terminal; and
a reference voltage output node disposed between the two resistors.

24. The internal voltage generator for a semiconductor memory apparatus of claim 21, wherein the driver controller comprises:
a bias signal generator configured to receive the reference voltage and output pull-up and pull-down bias voltages; and
an output controller configured to receive the pull-up and pull-down bias voltages and generate the first pull-up and pull-down control signals in response to the pull-up and pull-down bias voltages.

25. The internal voltage generator for a semiconductor memory apparatus of claim 21, wherein when the pull-up driver is turned off, the second pull-up control signal is a value configured to increase to an internal power source voltage.

26. The internal voltage generator for a semiconductor memory apparatus of claim 21, wherein when the pull-down driver is turned off, the second pull-down control signal is a value configured to decrease to a ground voltage.

27. The internal voltage generator for a semiconductor memory apparatus of claim 25, wherein the pull-up and pull-down drivers are configured to be turned off when the internal voltage is insufficient to inverse an output of the pull-up amplifier.

28. The internal voltage generator for a semiconductor memory apparatus of claim 26, wherein the pull-up and pull-down drivers are configured to be turned off when the internal voltage is insufficient to inverse an output of the pull-down amplifier.
